(19) United States
(12) Patent Application Publication
(10) Pub. No.: US 2026/0155160 A1
(43) Pub. Date: Jun. 4, 2026

(54) MEMORY APPARATUS AND OPERATION METHOD OF MEMORY APPARATUS

(71) Applicant: SK hynix Inc., Gyeonggi-do (KR)

(72) Inventors: Moo Hui PARK, Gyeonggi-do (KR); Jeong Ho YI, Gyeonggi-do (KR); Jung Hyuk YOON, Gyeonggi-do (KR); Tae Ho KIM, Gyeonggi-do (KR); Taek Seung KIM, Gyeonggi-do (KR); Jun Ho CHEON, Gyeonggi-do (KR)

(21) Appl. No.: 19/098,924

(22) Filed: Apr. 2, 2025

(30) Foreign Application Priority Data
Nov. 29, 2024 (KR) 10-2024-0175461

(51) Int. Cl. G11C 5/14; G11C 8/08; G11C 8/18

(52) U.S. Cl. CPC G11C 5/14; G11C 8/08; G11C 8/18

(57) ABSTRACT

A memory apparatus includes a first switch and a second switch configured to electrically connect or disconnect a first voltage line and a bit line in response to a first driving signal and a second driving signal; a third switch and a fourth switch configured to electrically connect or disconnect a second voltage line and a word line in response to a third driving signal and a fourth driving signal; a memory cell electrically connected between the bit line and the word line; and a signal level control circuit configured to differentially control turn-on degrees of the third and fourth switches when a forward enable signal is enabled, and differentially control turn-on degrees of the first and second switches when a reverse enable signal is enabled.

### CROSS-REFERENCE TO RELATED APPLICATION

This application claims priority under 35 U.S.C. § 119(a) to Korean Patent Application No. 10-2024-0175461 filed on Nov. 29, 2024, which is incorporated herein by reference in its entirety.

### BACKGROUND

### 1. Technical Field

Embodiments of the present disclosure relate to an integrated circuit technology, and more particularly, to a memory apparatus and an operation method thereof.

### 2. Related Art

Recently, with miniaturization, low power consumption, high performance, and diversification of electronic devices, there is a demand for memories capable of storing information in various electronic appliances such as computers and portable communication devices. In addition, research on memories having various characteristics is also ongoing.

Memories under research include memories that can store data by using the characteristic of switching between different resistance states depending on a voltage or a current applied. Such memories include a resistive random access memory (RRAM), a phase-change random access memory (PRAM), a ferroelectric random access memory (FRAM), a magnetic random access memory (MRAM), an e-fuse, and the like.

### SUMMARY

In an embodiment of the present disclosure, a memory apparatus may include a first switch configured to electrically connect or disconnect a first voltage line and a second switch in response to a first driving signal; the second switch configured to electrically connect or disconnect the first switch and a bit line in response to a second driving signal; a third switch configured to electrically connect or disconnect a second voltage line and a fourth switch in response to a third driving signal; the fourth switch configured to electrically connect or disconnect the third switch and a word line in response to a fourth driving signal; a memory cell electrically connected between the bit line and the word line; and a signal level control circuit configured to differentially control turn-on degrees of the third switch and the fourth switch when a forward enable signal is enabled and differentially control turn-on degrees of the first switch and the second switch when a reverse enable signal is enabled.

In another embodiment of the present disclosure, a memory apparatus may include a first transistor connected to a first voltage line; a second transistor connected between the first transistor and a bit line; a third transistor connected to a second voltage line; and a fourth transistor connected between the third transistor and a word line. When a forward enable signal is enabled, turn-on degrees of the third and fourth transistors may be reduced, and when a reverse enable signal is enabled, turn-on degrees of the first and second transistors may be reduced.

In an embodiment of the present disclosure, an operation method of a memory apparatus may include enabling a forward enable signal for causing a forward current to flow through a memory cell; turning on, in response to the forward enable signal, first and second switches to provide a current to the memory cell; and turning on, in response to the forward enable signal, third and fourth switches, through which the current flows from the memory cell, at different turn-on degrees.

### BRIEF DESCRIPTION OF THE DRAWINGS

FIGS. 1 to 3 are diagrams for describing a write operation and a read operation of a memory apparatus in accordance with an embodiment of the present disclosure.

FIG. 4 is a diagram for describing the configuration of the memory apparatus in accordance with the embodiment of the present disclosure.

FIG. 5 is a diagram for describing a signal level control circuit of the memory apparatus in accordance with the embodiment of the present disclosure.

FIGS. 6 and 7 are timing diagrams for describing the operation of the memory apparatus in accordance with the embodiment of the present disclosure.

### DETAILED DESCRIPTION

Various embodiments of the present disclosure are directed to providing a memory apparatus for reducing a spike current applied to a memory cell when the memory cell is turned on, and an operation method thereof.

The durability of a memory cell can be improved.

Hereafter, embodiments in accordance with the technical spirit of the present disclosure are described with reference to the accompanying drawings.

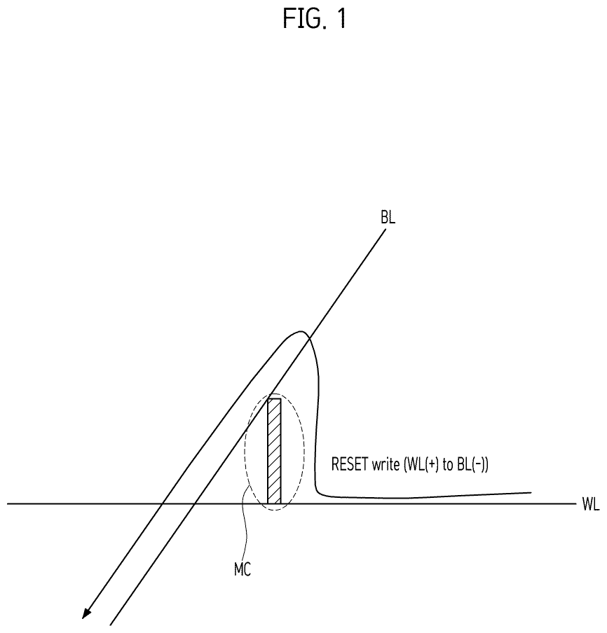

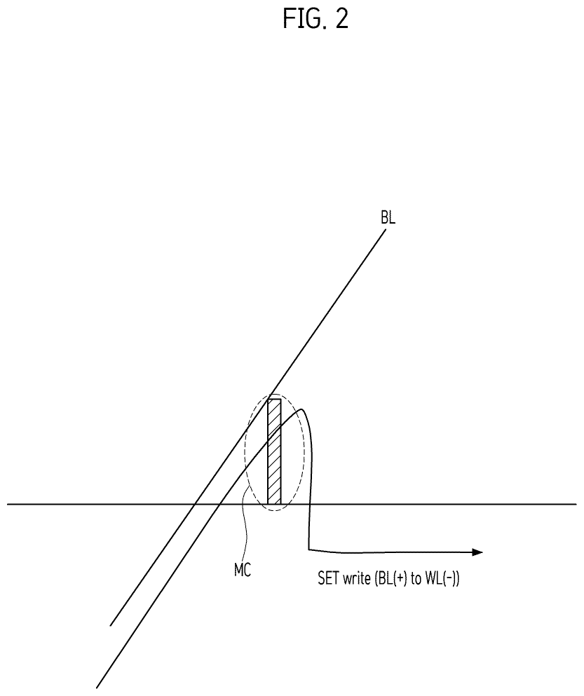

FIGS. 1 to 3 are diagrams for describing a write operation and a read operation of a memory apparatus in accordance with an embodiment of the present disclosure. In particular, FIGS. 1 and 2 are diagrams for describing the write operation in accordance with the embodiment of the present disclosure.

FIG. 1 is a diagram for describing a reset write operation RESET write of storing reset data in a memory cell MC. The memory cell MC has a threshold voltage that changes depending on the direction of a current passing therethrough. For example, the threshold voltage level of the memory cell MC is changed between a first level and a second level depending on the direction of a current passing therethrough. The first level is a level higher than the second level. When the threshold voltage level of the memory cell MC is the first level, the memory cell MC is in a reset state storing reset data. When the threshold voltage level of the memory cell MC is the second level, the memory cell MC is in a set state storing set data.

Referring to FIG. 1, the memory cell MC is electrically connected between a bit line BL and a word line WL. The reset write operation RESET write is an operation for changing the state of the memory cell MC to a reset state by storing reset data in the memory cell MC. For example, the memory cell MC is turned on by providing a first voltage to the word line WL and providing a second voltage to the bit line BL, and a current is allowed to flow from the word line WL to the bit line BL through the turned-on memory cell MC, thereby storing reset data in the memory cell MC. In such a case, the first voltage is a voltage at a higher level than the second voltage. The first voltage is a positive voltage and the second voltage is a negative voltage.

FIG. 2 is a diagram for describing a set write operation SET write of storing set data in the memory cell MC.

Referring to FIG. 2, the memory cell MC is electrically connected between the bit line BL and the word line WL. The set write operation SET write is an operation for changing the state of the memory cell MC to a reset state by storing set data in the memory cell MC. For example, the memory cell MC is turned on by providing the first voltage to the bit line BL and providing the second voltage to the word line WL, and a current is allowed to flow from the bit line BL to the word line WL through the turned-on memory cell MC, thereby storing set data in the memory cell MC. In such a case, the first voltage is a voltage of a higher level than the second voltage. The first voltage is a positive voltage and the second voltage is a negative voltage.

In an embodiment, when the threshold voltage of the memory cell MC is at a first level higher than a second level, it can be said that the memory cell MC has changed to a state of storing reset data, that is, a reset state. When the threshold voltage of the memory cell MC is at the second level lower than the first level, it can be said that the memory cell MC has changed to a state of storing set data, that is, a set state.

That is, the threshold voltage level of the memory cell MC storing reset data is higher than the threshold voltage level of the memory cell MC storing set data.

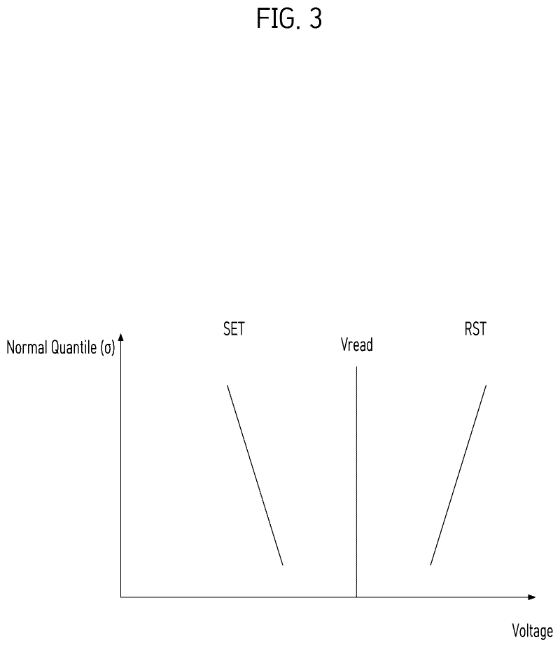

FIG. 3 is a diagram for describing the read operation of the memory cell MC that is transitioned between the reset state and the set state.

Referring to FIG. 3, the threshold voltage level of the memory cell MC in the set state SET is lower than the threshold voltage level of the memory cell MC in the reset state RST.

In an embodiment, during the read operation, a read voltage Vread is provided to the memory cell MC, and data stored in the memory cell MC is determined based on whether the memory cell MC is turned on. In such a case, a level difference between voltages applied to the bit line BL and the word line WL corresponds to the level of the read voltage Vread. That is, the level of the read voltage Vread is higher than the threshold voltage level of the memory cell MC in the set state SET and lower than the threshold voltage level of the memory cell MC in the reset state RST.

Accordingly, during the read operation, the memory cell MC in the set state SET to which the read voltage Vread is provided is turned on because a voltage higher than the threshold voltage is provided to the memory cell MC. On the other hand, during the read operation, the memory cell MC in the reset state RST to which the read voltage Vread is provided is turned off because a voltage lower than the threshold voltage is provided to the memory cell MC.

Accordingly, during the read operation, data stored in the memory cell MC is determined by providing the read voltage Vread to the memory cell MC.

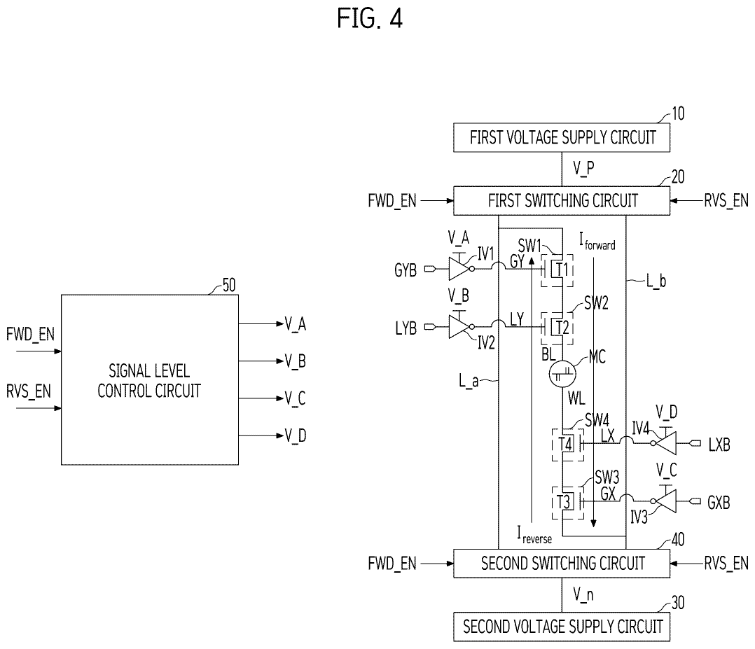

FIG. 4 is a diagram for describing the configuration of the memory apparatus in accordance with the embodiment of the present disclosure. As described in FIGS. 1 to 3, the memory apparatus including a memory cell that stores data according to the direction of a current passing therethrough is configured as illustrated in FIG. 4.

Referring to FIG. 4, the memory apparatus in accordance with the embodiment of the present disclosure includes a first voltage supply circuit 10, a first switching circuit 20, a second voltage supply circuit 30, a second switching circuit 40, a signal level control circuit 50, first to fourth address signal driving circuits IV1 to IV4, first to fourth switches SW1 to SW4, and a memory cell MC.

In an embodiment, the first voltage supply circuit 10 is a circuit that supplies a first voltage V_p to the first switching circuit 20. The first voltage V_p is a voltage with a higher level than a second voltage V_n. The first voltage V_p is a positive voltage, and the second voltage V_n is a negative voltage.

In an embodiment, the first switching circuit 20 provides the first voltage V_p to one of a first voltage line L_a and a second voltage line L_b. For example, the first switching circuit 20 provides the first voltage V_p to one of the first voltage line L_a and the second voltage line L_b based on a forward enable signal FWD_EN and a reverse enable signal RVS_EN. More specifically, when the forward enable signal FWD_EN is enabled, the first switching circuit 20 provides the first voltage V_p to the first voltage line L_a. When the reverse enable signal RVS_EN is enabled, the first switching circuit 20 provides the first voltage V_p to the second voltage line L_b.

In an embodiment, the second voltage supply circuit 30 is a circuit that supplies the second voltage V_n with a lower level than the first voltage V_p to the second switching circuit 40.

In an embodiment, the second switching circuit 40 provides the second voltage V_n to one of the first voltage line L_a and the second voltage line L_b. For example, the second switching circuit 40 provides the second voltage V_n to one of the first voltage line L_a and the second voltage line L_b based on the forward enable signal FWD_EN and the reverse enable signal RVS_EN. More specifically, when the forward enable signal FWD_EN is enabled, the second switching circuit 40 provides the second voltage V_n to the second voltage line L_b. When the reverse enable signal RVS_EN is enabled, the second switching circuit 40 provides the second voltage V_p to the first voltage line L_a.

In an embodiment, the first to fourth address driving circuits IV1 to IV4 drive input address signals GYB, LYB, GXB, and LXB to levels of driving voltages V_A, V_B, V_C, and V_D, and provide the driven signals to the first to fourth switches SW1 to SW4, respectively.

In an embodiment, for example, the first address driving circuit IV1 drives a global column address signal GYB to the level of a first driving voltage V_A and provides the driven signal to the first switch SW1 as a first driving signal GY. For example, the first address driving circuit IV1 includes an inverter that receives the first driving voltage V_A through a voltage input terminal thereof, receives the global address signal GYB through a signal input terminal thereof, and outputs the first driving signal GY through a signal output terminal thereof.

In an embodiment, the second address driving circuit IV2 drives a local column address signal LYB to the level of a second driving voltage V_B and provides the driven signal to the second switch SW2 as a second driving signal LY. For example, the second address driving circuit IV2 includes an inverter that receives the second driving voltage V_B through a voltage input terminal thereof, receives the local address signal LYB through a signal input terminal thereof, and outputs the second driving signal LY through a signal output terminal thereof.

In an embodiment, the third address driving circuit IV3 drives a global row address signal GXB to the level of a third driving voltage V_C and provides the driven signal to the third switch SW3 as a third driving signal GX. For example, the third address driving circuit IV3 includes an inverter that receives the third driving voltage V_C through a voltage input terminal thereof, receives the global row address signal GXB through a signal input terminal thereof, and outputs the third driving signal GX through a signal output terminal thereof.

In an embodiment, the fourth address driving circuit IV4 drives a local row address signal LXB to the level of a fourth driving voltage V_D and provides the driven signal to the fourth switching SW4 as a fourth driving signal LX. For example, the fourth address driving circuit IV4 includes an inverter that receives the fourth driving voltage V_C through a voltage input terminal thereof, receives the local row address signal LXB through a signal input terminal thereof, and outputs the fourth driving signal LX through a signal output terminal thereof.

In an embodiment, the first to fourth switches SW1 to SW4 are switches that select at least one from a plurality of memory cells in response to the global column address signal GYB, the global row address signal GXB, the local column address signal LYB, and the local row address signal LXB. For convenience of description, FIG. 4 illustrates the switches SW1 to SW4 that select one memory cell.

In an embodiment, the first switch SW1 electrically connects or disconnects the first voltage line L_a and the second switch SW2 in response to the first driving signal GY. The first switch SW1 includes a first transistor T1 having a gate that receives the first driving signal GY and a drain and a source to which the first voltage line L_a and the second switch SW2 are connected, respectively. The turn-on degree of the first transistor T1 varies depending on the level of the first driving signal GY. When the first transistor T1 is an NMOS transistor, the turn-on degree of the first transistor T1 increases as the level of the first driving signal GY increases.

In an embodiment, the second switch SW2 electrically connects or disconnects the first switch SW1 and the bit line BL in response to the second driving signal LY. The second switch SW2 includes a second transistor T2 having a gate that receives the second driving signal LY and a drain and a source to which the first switch SW1 and the bit line BL are connected, respectively. The turn-on degree of the second transistor T2 varies depending on the level of the second driving signal LY. When the second transistor T2 is an NMOS transistor, the turn-on degree of the second transistor T2 increases as the level of the second driving signal LY increases.

In an embodiment, the third switch SW3 electrically connects or disconnects the second voltage line L_b and the fourth switch SW4 in response to the third driving signal GX. The third switch SW3 includes a third transistor T3 having a gate that receives the third driving signal GX and a drain and a source to which the second voltage line L_b and the fourth switch SW4 are connected, respectively. The turn-on degree of the third transistor T3 varies depending on the level of the third driving signal GX. When the third transistor T3 is an NMOS transistor, the turn-on degree of the third transistor T3 increases as the level of the third driving signal GX increases.

In an embodiment, the fourth switch SW4 electrically connects or disconnects the third switch SW3 and the word line WL in response to the fourth driving signal LX. The fourth switch SW4 includes a fourth transistor T4 having a gate that receives the fourth driving signal LX and a drain and a source to which the third switch SW3 and the word line WL are connected, respectively. The turn-on degree of the fourth transistor T4 varies depending on the level of the fourth driving signal LX. When the fourth transistor T4 is an NMOS transistor, the turn-on degree of the fourth transistor T4 increases as the level of the fourth driving signal LX increases.

In an embodiment, the memory cell MC is electrically connected between the bit line BL and the word line WL. A threshold voltage level of the memory cell MC is changed to one of a first level and a second level according to the direction of a current passing therethrough. The first level is a level higher than the second level. When the threshold voltage level of the memory cell MC is the first level, the memory cell MC is in a reset state that stores reset data. When the threshold voltage level of the memory cell MC is the second level, the memory cell MC is in a set state that stores set data. The memory cell MC includes a chalcogenide series material.

In an embodiment, the signal level control circuit 50 changes the levels of the first to fourth driving voltages V_A, V_B, V_C, and V_D based on the forward enable signal FWD_EN and the reverse enable signal RVS_EN. For example, when the forward enable signal FWD_EN is enabled, the signal level control circuit 50 outputs the first and second driving voltages V_A and V_B as voltages at the first level, outputs the third driving voltage V_C as a voltage at the second level, and outputs the fourth driving voltage V_D as a voltage at a third level. When the reverse enable signal RVS_EN is enabled, the signal level control circuit 50 outputs the third and fourth driving voltages V_C and V_D as voltages at the first level, outputs the first voltage V_A as a voltage at the second level, and outputs the second driving voltage V_B as a voltage at the third level. The voltage at the first level has a higher level than the voltage at the second level. The voltage at the second level has a higher level than the voltage at the third level.

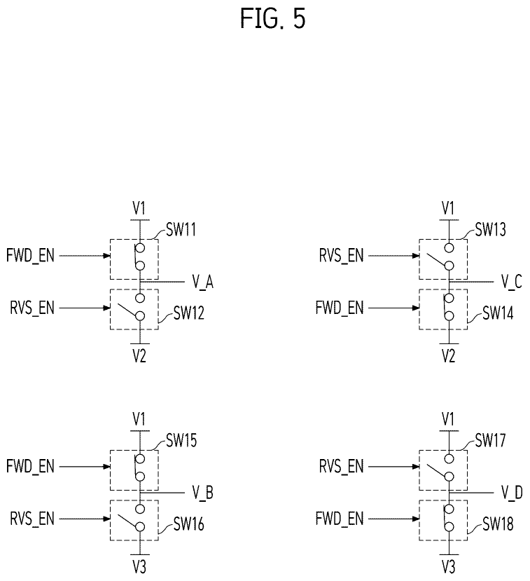

A detailed description of the signal level control circuit 50 is replaced with the description of FIG. 5.

FIG. 5 is a diagram for describing the signal level control circuit of the memory apparatus in accordance with the embodiment of the present disclosure.

Referring to FIG. 5, the signal level control circuit 50 of the memory apparatus in accordance with the embodiment of the present disclosure includes fifth to twelfth switches SW11 to SW18. The fifth to twelfth switches SW11 to SW18 are configured to change the levels of the first to fourth driving voltages V_A, V_B, V_C, and V_D.

In an embodiment, the fifth and sixth switches SW11 and SW12 are configured to change the level of the first driving voltage V_A. For example, the fifth and sixth switches SW11 and SW12 change the level of the first driving voltage V_A based on the forward enable signal FWD_EN and the reverse enable signal RVS_EN. More specifically, the fifth switch SW11 outputs a voltage V1 at the first level as the first driving voltage V_A when the forward enable signal FWD_EN is enabled. The sixth switch SW12 outputs a voltage V2 at the second level as the first driving voltage V_A when the reverse enable signal RVS_EN is enabled.

In an embodiment, the seventh and eighth switches SW13 and SW14 are configured to change the level of the third driving voltage V_C. For example, the seventh and eighth switches SW13 and SW14 change the level of the third driving voltage V_C based on the forward enable signal FWD_EN and the reverse enable signal RVS_EN. More specifically, the seventh switch SW13 outputs the voltage V1 at the first level as the third driving voltage V_C when the reverse enable signal RVS_EN is enabled. The seventh switch SW13 outputs the voltage V2 at the second level as the third driving voltage V_C when the forward enable signal FWD_EN is enabled.

In an embodiment, the ninth and tenth switches SW15 and SW16 are configured to change the level of the second driving voltage V_B. For example, the ninth and tenth switches SW15 and SW16 change the level of the second driving voltage V_B based on the forward enable signal FWD_EN and the reverse enable signal RVS_EN. More specifically, the ninth switch SW15 outputs the voltage V1 at the first level as the second driving voltage V_B when the forward enable signal FWD_EN is enabled. The tenth switch SW16 outputs the voltage V3 at the third level as the second driving voltage V_B when the reverse enable signal RVS_EN is enabled.

In an embodiment, the eleventh and twelfth switches SW17 and SW18 are configured to change the level of the fourth driving voltage V_D. For example, the eleventh and twelfth switches SW17 and SW18 change the level of the fourth driving voltage V_D based on the forward enable signal FWD_EN and the reverse enable signal RVS_EN. More specifically, the eleventh switch SW17 outputs the voltage V1 at the first level as the fourth driving voltage V_D when the reverse enable signal RVS_EN is enabled. The twelfth switch SW18 outputs the voltage V3 at the third level as the fourth driving voltage V_D when the forward enable signal FWD_EN is enabled. The voltage V1 at the first level is a level higher than the voltage V2 at the second level, and the voltage V2 at the second level is a level higher than the voltage V3 at the third level.

The signal level control circuit 50 in accordance with the embodiment of the present disclosure configured above can output the voltage V1 at the first level as the first and second driving voltages V_A and V_B, output the voltage V2 at the second level as the third driving voltage V_C, and output the voltage V3 at the third level as the fourth driving voltage V_D when the forward enable signal FWD_EN is enabled. When the reverse enable signal RVS_EN is enabled, the signal level control circuit 50 can output the voltage V1 at the first level as the third and fourth driving voltages V_C and V_D, output the voltage V2 at the second level as the first driving voltage V_A, and output the voltage V3 at the third level as the second driving voltage V_B.

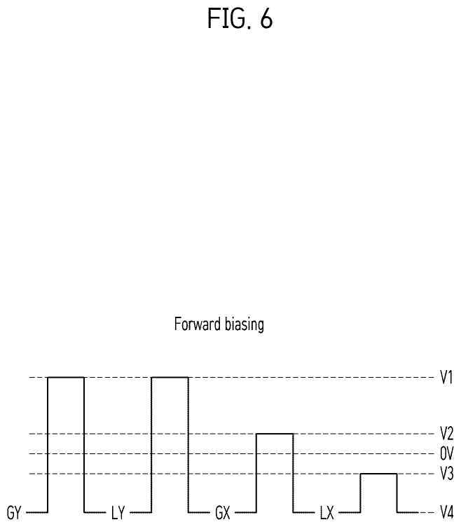

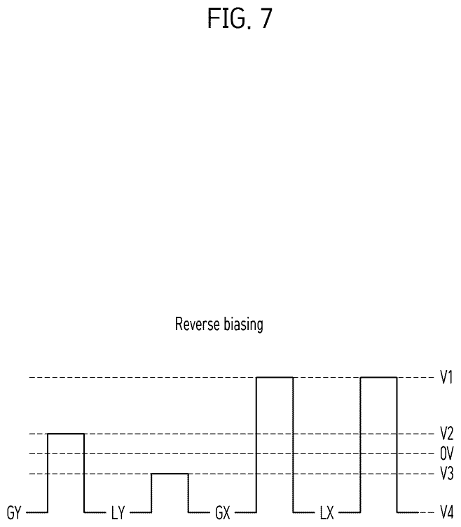

FIGS. 6 and 7 are timing diagrams for describing the operation of the memory apparatus in accordance with the embodiment of the present disclosure.

FIG. 6 illustrates the levels of the first to fourth driving signals GY, LY, GX, and LX when a forward current flows through the memory cell MC (forward biasing). Referring back to FIG. 4, when a forward current I_{foward} flows through the memory cell MC, the first switching circuit 20 provides the first voltage V_p to the first voltage line L_a and the second switching circuit 40 provides the second voltage V_n to the second voltage line L_b based on the forward enable signal FWD_EN. In such a case, the first and second switches SW1 and SW2 are turned on to electrically connect the first voltage line L_a and the bit line BL. In addition, the third and fourth switches SW3 and SW4 are turned on to electrically connect the second voltage line L_b and the word line WL. Accordingly, the memory cell MC is passed through by the forward current I_{foward} flowing to the word line WL and the second voltage line L_b through the first voltage line L_a and the bit line BL.

Referring to FIG. 6, the first and second switches SW1 and SW2 are turned on by receiving the first and second driving signals GY and LY that are enabled by being driven by the voltage V1 at the first level. The third switch SW3 is turned on by receiving the third driving signal GX that is enabled by being driven by the voltage V2 at the second level. The fourth switch SW4 is turned on by receiving the fourth driving signal LX that is enabled by being driven by the voltage V3 at the third level. The turn-on degrees of the first to fourth switches SW1 to SW4 constituted by the NMOS transistors T1 to T4 are determined according to the levels of the driving signals GY, LY, GX, and LX received in the gates of the NMOS transistors T1 to T4. The voltage V1 at the first level is a voltage higher than the voltage V2 at the second level, and the voltage V2 at the second level is a voltage higher than the voltage V3 at the third level. The voltage V1 at the first level is a pumping voltage, the voltage V2 at the second level is an external voltage, and the voltage V3 at the third level is a negative voltage with a higher level than a voltage V4 at a fourth level. A level difference between the second voltage V_n and the voltage V3 at the third level is a level difference that enables the first and third switches SW1 and SW3 to be turned on.

Accordingly, when the forward current I_{forward} flows through the memory cell MC, the turn-on degrees of the first and second switches SW1 and SW2 are greatest, and the turn-on degree of the third switch SW3 is less than those of the first and second switches SW1 and SW2 and is greater than that of the fourth switch SW4. The turn-on degree of the fourth switch SW4 is least. Accordingly, the amount of the forward current I_{forward} passing through the memory cell MC is reduced depending on the turn-on degrees of the third and fourth switches SW3 and SW4 with small turn-on degrees.

As a result, when the memory cell MC is turned on by the forward current I_{forward}, the memory apparatus in accordance with the embodiment of the present disclosure can reduce the amount of forward current I_{forward} by reducing the turn-on degrees of the third and fourth switches SW3 and SW4, thereby reducing a rapid current change, for example, a spike current, when the memory cell MC is turned on.

FIG. 7 illustrates the levels of the first to fourth driving signals GY, LY, GX, and LX when reverse current flows through the memory cell MC (reverse biasing). Referring back to FIG. 4, when the reverse current Iᵣₑᵥₑᵣₛₑ flows through the memory cell MC, the first switching circuit 20 provides the first voltage V_p to the second voltage line L_b and the second switching circuit 40 provides the second voltage V_n to the first voltage line L_a based on the reverse enable signal RVS_EN. In such a case, the first and second switches SW1 and SW2 are turned on to electrically connect the first voltage line L_a and the bit line BL. In addition, the third and fourth switches SW3 and SW4 are turned on to electrically connect the second voltage line L_b and the word line WL. Accordingly, the memory cell MC is passed through by the reverse current Iᵣₑᵥₑᵣₛₑ flowing to the bit line BL and the first voltage line L_a through the second voltage line L_b and the word line WL.

Referring to FIG. 7, the third and fourth switches SW3 and SW4 are turned on by receiving the third and fourth driving signals GX and LX that are enabled by being driven by the voltage V1 at the first level. The first switch SW1 is turned on by receiving the first driving signal GY that is enabled by being driven by the voltage V2 at the second level. The second switch SW2 is turned on by receiving the second driving signal LY that is enabled by being driven by the voltage V3 at the third level. The turn-on degrees of the first to fourth switches SW1 to SW4 constituted by the NMOS transistors T1 to T4 are determined according to the levels of the driving signals GY, LY, GX, and LX received in the gates of the NMOS transistors T1 to T4. The voltage V1 at the first level is a voltage higher than the voltage V2 at the second level, and the voltage V2 at the second level is a voltage higher than the voltage V3 at the third level. The voltage V1 at the first level is a pumping voltage, the voltage V2 at the second level is an external voltage, and the voltage V3 at the third level is a negative voltage with a higher level than the voltage V4 at the fourth level.

Accordingly, when the reverse current Iᵣₑᵥₑᵣₛₑ flows through the memory cell MC, the turn-on degrees of the third and fourth switches SW3 and SW4 are greatest, and the turn-on degree of the first switch SW1 is less than those of the third and fourth switches SW3 and SW4 and is greater than that of the second switch SW2. The second switch SW2 may have the least turn-on degree. Accordingly, the amount of the reverse current Iᵣₑᵥₑᵣₛₑ passing through the memory cell MC is reduced depending on the turn-on degrees of the first and second switches SW1 and SW2 with lesser turn-on degrees.

As a result, when the memory cell MC is turned on by the reverse current Iᵣₑᵥₑᵣₛₑ, the memory apparatus in accordance with the embodiment of the present disclosure can reduce the amount of the reverse current Iᵣₑᵥₑᵣₛₑ by reducing the turn-on degrees of the first and second switches SW1 and SW2, thereby reducing a rapid current change, for example, a spike current, when the memory cell MC is turned on.

Accordingly, when the memory cell MC is turned on by the forward current I_{forward} and the reverse current Iᵣₑᵥₑᵣₛₑ, the memory apparatus in accordance with the embodiment of the present disclosure can reduce the spike current generated when the memory cell is turned on, thereby reducing the stress on the memory cell due to the spike current. Consequently, the memory apparatus in accordance with the embodiment of the present disclosure can be effective in improving the durability of the memory cell.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure. Furthermore, the embodiments may be combined to form additional embodiments.

What is claimed is:

1. A memory apparatus comprising:
a first switch configured to electrically connect or disconnect a first voltage line and a second switch in response to a first driving signal;
the second switch configured to electrically connect or disconnect the first switch and a bit line in response to a second driving signal;
a third switch configured to electrically connect or disconnect a second voltage line and a fourth switch in response to a third driving signal;
the fourth switch configured to electrically connect or disconnect the third switch and a word line in response to a fourth driving signal;
a memory cell connected between the bit line and the word line; and
a signal level control circuit configured to differentially control turn-on degrees of the third switch and the fourth switch when a forward enable signal is enabled, and differentially control turn-on degrees of the first switch and the second switch when a reverse enable signal is enabled.

2. The memory apparatus of claim 1, further comprising:
a first address driving circuit configured to drive a global column address signal to a level of a first driving voltage to output a first driving signal;
a second address driving circuit configured to drive a local column address signal to a level of a second driving voltage to output a second driving signal;
a third address driving circuit configured to drive a global row address signal to a level of a third driving voltage to output a third driving signal; and
a fourth address driving circuit configured to drive a local row address signal to a level of a fourth driving voltage to output a fourth driving signal.

3. The memory apparatus of claim 2, wherein, when the forward enable signal is enabled, the signal level control circuit is configured to output the first driving voltage and the second driving voltage having a first level, output the third driving voltage having a second level, and output the fourth driving voltage having a third level.

4. The memory apparatus of claim 3, wherein, when the reverse enable signal is enabled, the signal level control circuit is configured to output the third driving voltage and the fourth driving voltage having the first level, output the first driving voltage having the second level, and output the second driving voltage having the third level.

5. The memory apparatus of claim 4, wherein the first level is higher than the second level, and the second level is higher than the third level.

6. The memory apparatus of claim 5, wherein each of the first to fourth switches includes an NMOS transistor.

7. The memory apparatus of claim 6, wherein turn-on degrees of the first to fourth switches are determined according to levels of the first to fourth driving signals input to the first to fourth switches, respectively.

8. The memory apparatus of claim 7, wherein, when the forward enable signal is enabled, the turn-on degrees of the first and second switches are greatest and the turn-on degree of the third switch is controlled to be greater than the turn-on degree of the fourth switch.

9. The memory apparatus of claim 8, wherein, when the reverse enable signal is enabled, the turn-on degrees of the third and fourth switches are greatest and the turn-on degree of the first switch is controlled to be greater than the turn-on degree of the second switch.

10. A memory apparatus comprising:
a first transistor connected to a first voltage line;
a second transistor connected between the first transistor and a bit line;
a third transistor connected to a second voltage line; and
a fourth transistor connected between the third transistor and a word line,
wherein:
when a forward enable signal is enabled, turn-on degrees of the third and fourth transistors are reduced; and
when a reverse enable signal is enabled, turn-on degrees of the first and second transistors are reduced.

11. The memory apparatus of claim 10, wherein:
the turn-on degree of the first transistor varies depending on a level of a first driving signal;
the turn-on degree of the second transistor varies depending on a level of a second driving signal;
the turn-on degree of the third transistor varies depending on a level of a third driving signal; and
the turn-on degree of the fourth transistor varies depending on a level of a fourth driving signal.

12. The memory apparatus of claim 11, further comprising:
a signal level control circuit configured to change a level of each of a first driving voltage, a second driving voltage, a third driving voltage, and a fourth driving voltage in response to the forward enable signal and the reverse enable signal;
a first address driving circuit configured to drive a global column address signal to a level of the first driving voltage to output a first driving signal;
a second address driving circuit configured to drive a local column address signal to a level of the second driving voltage to output a second driving signal;
a third address driving circuit configured to drive a global row address signal to a level of the third driving voltage to output a third driving signal; and
a fourth address driving circuit configured to drive a local row address signal to a level of the fourth driving voltage to output a fourth driving signal.

13. The memory apparatus of claim 12, wherein, when the forward enable signal is enabled, the signal level control circuit is configured to output the first and second driving voltages having a first level, output the third driving voltage having a second level, and output the fourth driving voltage having a third level.

14. The memory apparatus of claim 13,
wherein, when the reverse enable signal is enabled, the signal level control circuit is configured to output the third and fourth driving voltages having the first level, output the first driving voltage having the second level, and output the second driving voltage having the third level, and
wherein the first level is higher than the second level, and the second level is higher than the third level.

15. An operation method of a memory apparatus, the operation method comprising:
enabling a forward enable signal for causing a forward current to flow through a memory cell;
turning on, in response to the forward enable signal, first and second switches to provide a current to the memory cell; and
turning on, in response to the forward enable signal, third and fourth switches, through which the current flows from the memory cell, at different turn-on degrees.

16. The operation method of a memory apparatus of claim 15, wherein the turning-on of the first and second switches comprises:
providing driving signals having a same level to the first and second switches.

17. The operation method of a memory apparatus of claim 16, wherein the turning-on of the third and fourth switches comprises:
providing driving signals having different levels to the third and fourth switches.

18. The operation method of a memory apparatus of claim 15, further comprising:
enabling a reverse enable signal for causing a reverse current to flow through the memory cell;
turning on, in response to the reverse enable signal, the third and fourth switches to provide a current to the memory cell; and
turning on, in response to the reverse enable signal, the first and second switches, through which the current flows from the memory cell, at different turn-on degrees.

19. The operation method of a memory apparatus of claim 18, wherein turning-on the third and fourth switches comprises:
providing driving signals having a same level to the third and fourth switches.

20. The operation method of a memory apparatus of claim 19, wherein turning-on the first and second switches comprises:
providing driving signals having different levels to the first and second switches.
